(19) United States
(12) Patent Application Publication
(10) Pub. No.: US 2024/0231445 A9
(43) Pub. Date: Jul. 11, 2024

(54) AIR SHROUD HAVING BUILT IN AIR MOVERS FOR ENHANCED COOLING

(71) Applicant: Dell Products L.P., Round Rock, TX (US)

(72) Inventor: Robert B. CURTIS, Georgetown, TX (US)

(73) Assignee: Dell Products L.P., Round Rock, TX (US)

(21) Appl. No.: 17/972,236

(22) Filed: Oct. 24, 2022

(51) Int. Cl. G06F 1/20

(52) U.S. Cl. CPC G06F 1/20

(57) ABSTRACT

An air shroud may include a plurality of channels including at least a first channel configured to direct airflow driven by one or more chassis-level air movers from outside a chassis enclosing the air shroud into the chassis and into the first channel and a second channel configured to direct airflow driven by the one or more chassis-level air movers from outside the chassis into the chassis and into the second channel, and an opening formed in the air shroud and fluidically configured to be interfaced between the second channel and a shroud air mover such that, when the shroud air mover operates in a plurality of modes comprising a first mode in which the shroud air mover is inactive and a second mode in which the shroud air mover is active, airflow through the second channel is greater in the second mode than in the first mode.

### TECHNICAL FIELD

The present disclosure relates in general to information handling systems, and more particularly to using air shrouds with one or more built in air movers to enhance cooling of information handling resources.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction, and damage leading to a shortened component lifespan. Accordingly, air movers (e.g., cooling fans and blowers) have often been used in information handling systems to cool information handling systems and their components.

Air shrouds may be used to balance airflow between components of an information handling system (e.g., between a central processing unit (CPU) and memory) based on the respective cooling needs. However, the respective cooling needs for the CPU and memory are dynamic and change based on the server workload. The design of traditional passive air shrouds does not account for the changing cooling needs of these components. Passive air shrouds are typically designed to limit or control the bypass of airflow around the CPU and memory. Openings in the air shrouds allow some airflow to pass through the openings for cooling of components other than CPUs and memory. However, with passive air shrouds, the remaining airflow must pass through the CPU heatsink and memory to provide cooling for those subsystems. With passive air shrouds, the CPU heatsink fin density can be manipulated to control how much airflow passes through the CPU heatsink compared to the memory. For example, a higher density CPU heatsink will result in more airflow through the memory while a lower density CPU heatsink will allow more airflow through the CPU heatsink. The problem with optimizing CPU and memory cooling based on CPU heatsink density is that, as memory power increases, more cooling is needed for the memory and increasing the CPU heatsink density only offers small benefit to the memory while reducing CPU cooling performance.

### SUMMARY

In accordance with the teachings of the present disclosure, the disadvantages and problems associated with cooling information handling resources via existing air shrouds may be substantially reduced or eliminated.

In accordance with embodiments of the present disclosure, an information handling system may include a chassis, a plurality of information handling resources enclosed within the chassis and including a first information handling resource and a second information handling resource, an air shroud enclosed within the chassis an including a plurality of channels including at least a first channel configured to direct airflow driven by one or more chassis-level air movers from outside the chassis into the chassis and proximate to the first information handling resource and a second channel configured to direct airflow driven by the one or more chassis-level air movers from outside the chassis into the chassis and proximate to the second information handling resource, and a shroud air mover mechanically coupled to the air shroud and fluidically coupled to the second channel via an opening formed in the air shroud and fluidically interfaced between the second channel and the shroud air mover, the shroud air mover configured to operate in a plurality of modes comprising a first mode in which the shroud air mover is inactive and a second mode in which the shroud air mover is active such that airflow through the second channel is greater in the second mode than in the first mode.

In accordance with these and other embodiments of the present disclosure, an air shroud may include a plurality of channels including at least a first channel configured to direct airflow driven by one or more chassis-level air movers from outside a chassis enclosing the air shroud into the chassis and into the first channel and a second channel configured to direct airflow driven by the one or more chassis-level air movers from outside the chassis into the chassis and into the second channel, and an opening formed in the air shroud and fluidically configured to be interfaced between the second channel and a shroud air mover such that, when the shroud air mover operates in a plurality of modes comprising a first mode in which the shroud air mover is inactive and a second mode in which the shroud air mover is active, airflow through the second channel is greater in the second mode than in the first mode.

In accordance with these and other embodiments of the present disclosure, a method may include, in a system having an air shroud enclosed within a chassis, and a plurality of channels including at least a first channel configured to direct airflow driven by one or more chassis-level air movers from outside the chassis into the chassis and a second channel configured to direct airflow driven by one or more chassis-level air movers from outside the chassis into the chassis and proximate to a second information handling resource, and the system further comprising a shroud air mover mechanically coupled to the air shroud and fluidically coupled to the second channel via an opening formed in the air shroud and fluidically interfaced between the second channel and the shroud air mover, operating the shroud air mover in a plurality of modes including a first mode in which the shroud air mover is inactive and a second mode in which the shroud air mover is active such that airflow through the second channel is greater in the second mode than in the first mode.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2 illustrates a perspective view of an example air shroud in accordance with embodiments of the present disclosure;

FIG. 3A illustrates a perspective view of an example information handling system including an air shroud in accordance with embodiments of the present disclosure;

FIG. 3B illustrates a perspective view of another example information handling system including an air shroud in accordance with embodiments of the present disclosure;

FIG. 4 illustrates a perspective view of an example information handling system including an air shroud having air shroud flappers in accordance with at least one embodiment of the present disclosure;

FIG. 5A illustrates a side view of an example information handling system including an air shroud having air shroud flappers in accordance with at least one embodiment of the present disclosure; and

FIG. 5B illustrates a side view of another example information handling system including an air shroud having air shroud flappers in accordance with at least one embodiment of the present disclosure.

### DETAILED DESCRIPTION

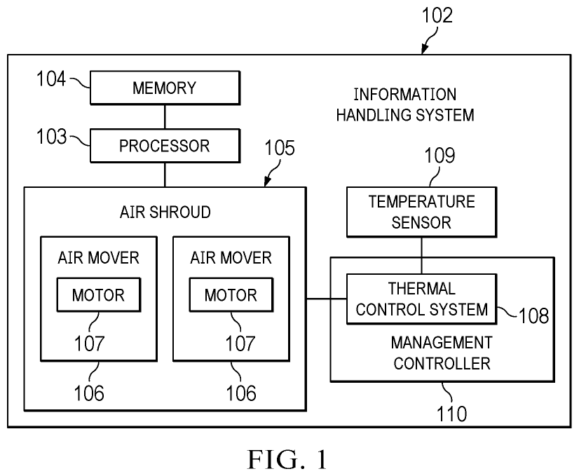

Preferred embodiments and their advantages are best understood by reference to FIGS. 1 through 5B, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house one or more servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104, an air shroud 105, one or more air movers 106, a management controller 110 comprising a thermal control system 108, and a temperature sensor 109.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time (e.g., computer-readable media). Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 106 may include any mechanical or electro-mechanical system, apparatus, or device operable to move air and/or other gases in order to cool information handling resources of information handling system 102. In some embodiments, air mover 106 may comprise a fan (e.g., a rotating arrangement of vanes or blades which act on the air). In other embodiments, air mover 106 may comprise a blower (e.g., a centrifugal fan that employs rotating impellers to accelerate air received at its intake and change the direction of the airflow). In these and other embodiments, rotating and other moving components of air mover 106 may be driven by a motor 107. The rotational speed of motor 107 may be controlled by an air mover control signal communicated from thermal control system 108 of management controller 110. In these and other embodiments, air mover 106 may be coupled to air shroud 105.

Management controller 110 may comprise any system, device, or apparatus configured to facilitate management and/or control of information handling system 102 and/or one or more of its component information handling resources. Management controller 110 may be configured to issue commands and/or other signals to manage and/or control information handling system 102 and/or its information handling resources. Management controller 110 may comprise a microprocessor, a microcontroller, DSP, ASIC, field programmable gate array (“FPGA”), EEPROM, or any combination thereof. Management controller 110 may also be configured to provide out-of-band management facilities for management of information handling system 102, for example via a management console communicatively coupled to management controller 110. Such management may be made by management controller 110 even if information handling system 102 is powered off or powered to a standby state. In certain embodiments, management controller 110 may include or may be an integral part of a baseboard management controller (BMC), a remote access controller (e.g., a Dell Remote Access Controller or Integrated Dell Remote Access Controller), or an enclosure controller.

As shown in FIG. 1, management controller 110 may include a thermal control system 108. Thermal control system 108 may include any system, device, or apparatus configured to receive one or more signals indicative of one or more temperatures within information handling system 102 (e.g., one or more signals from one or more temperature sensors 109), and based on such signals, calculate an air mover driving signal to maintain an appropriate level of cooling, increase cooling, or decrease cooling, as appropriate, and communicate such air mover driving signal to air mover 106. In these and other embodiments, thermal control system 108 may be configured to receive information from other information handling resources and calculate the air mover driving signal based on such received information in addition to temperature information. For example, thermal control system 108 may receive thermal requirement information of one or more information handling resources. In addition to temperature information collected from sensors within information handling system 102, thermal control system 108 may also calculate the air mover driving signal based on such information received from information handling resources. Management controller 110 comprising thermal control system 108 may determine, based on received signals, a selected operation mode from a plurality of operation modes of air mover 106.

Temperature sensor 109 may be any system, device, or apparatus (e.g., a thermometer, thermistor, etc.) configured to communicate a signal to processor 103 or another controller indicative of a temperature within information handling system 102. In many embodiments, information handling system 102 may comprise a plurality of temperature sensors 109, wherein each temperature sensor 109 detects a temperature of a particular component and/or location within information handling system 102.

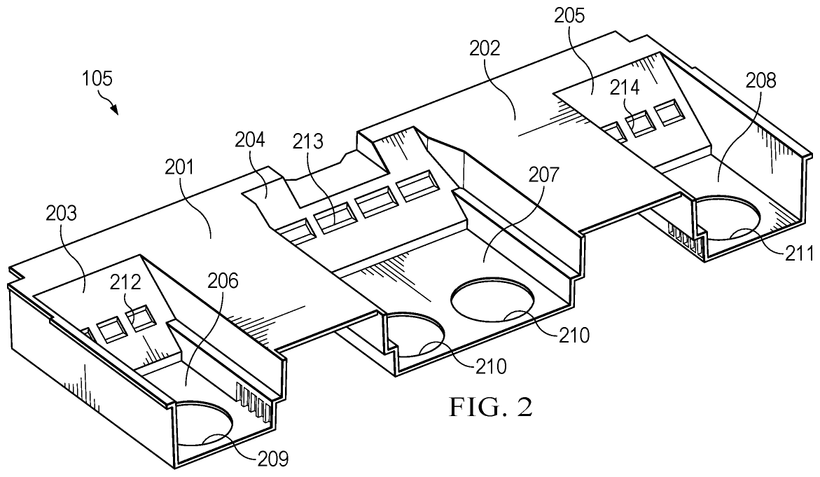

Air shroud 105 may include any system, device, or apparatus configured to direct airflow to cool information handling system components. Air shroud 105 may be positioned in front of chassis-level air movers external to air shroud 105, such that air shroud 105 may direct airflow from the air movers across components located under air shroud 105 and toward multiple components downstream of the chassis-level air movers. As illustrated in FIG. 2, air shroud 105 may define airflow channels so that air from the chassis-level air movers passes proximate to and cools information handling system components.

In addition to processor 103, memory 104, air shroud 105, air mover 106, management controller 110, and temperature sensor 109, information handling system 102 may include one or more other information handling resources. In addition, for the sake of clarity and exposition of the present disclosure, FIG. 1 depicts two air movers 106 and one temperature sensor 109. In embodiments of the present disclosure, information handling system 102 may include any number of air movers 106 and any number of temperature sensors 109.

FIG. 2 illustrates an air shroud 105 in accordance with embodiments of the present disclosure. Air shroud 105 may include air channels 201 and 202, down slope sections 203, 204, and 205, and memory covers 206, 207, and 208. Down slope sections 203, 204, and 205 may include one or more bypass ports 212, 213, and 214, respectively. Memory covers 206, 207, and 208 may also include air mover openings 209, 210, and 211, respectively. Air channels 201 and 202 of air shroud 105 may be placed over and enclose heat sinks thermally coupled to one or more processors 103. Air channel 201 may be located between down slope sections 203 and 204 and memory covers 209 and 210. Air channel 202 may be located between down slope sections 204 and 205 and memory covers 210 and 211. Down slope sections 203, 204, and 205 may slope downward from an edge of air shroud 105 proximate to chassis-level air movers and toward memory covers 206, 207, and 208, respectively, and direct airflow from chassis-level air movers flowing through bypass ports 212, 213, and 214 across memory covers 206, 207, and 208.

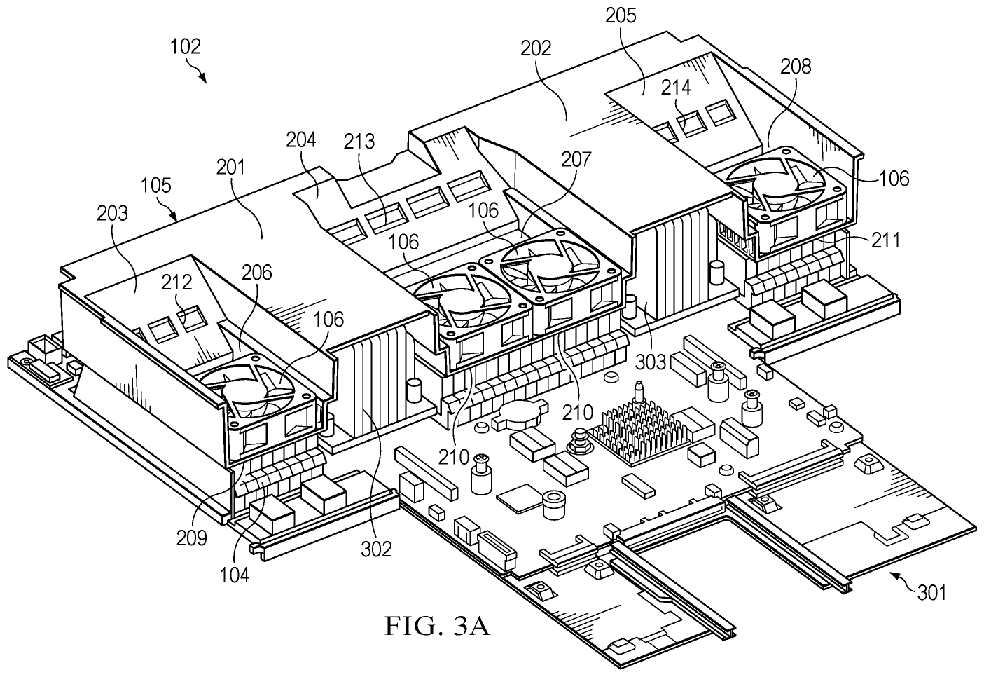

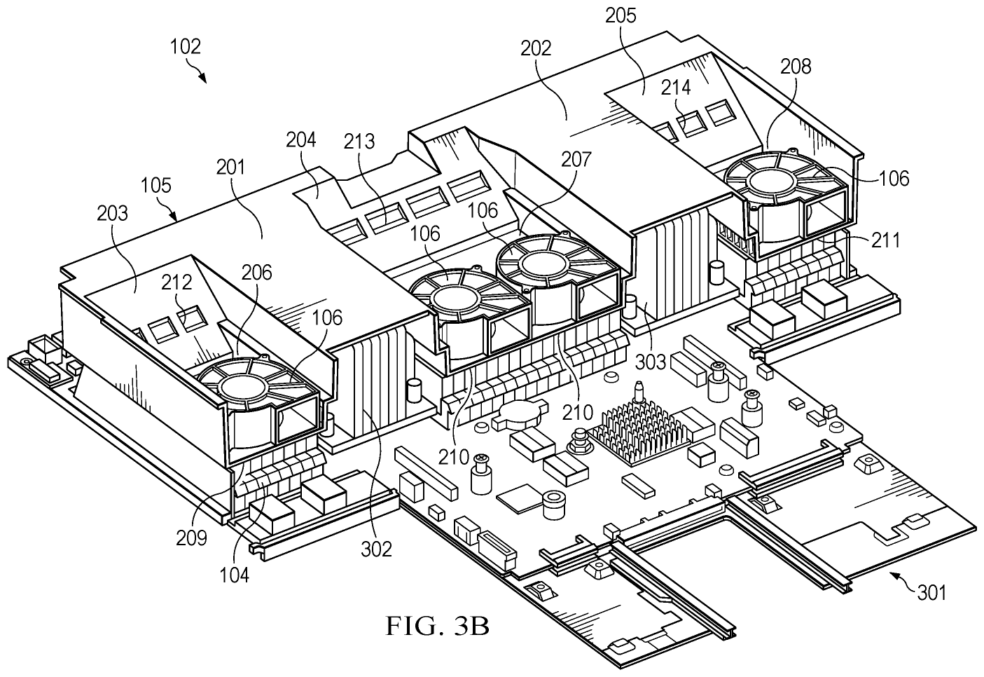

FIGS. 3A and 3B illustrate an information handling system 102 including an air shroud 105 and air movers 106, and other components 301 of information handling system 102 in accordance with embodiments of the present disclosure. In such embodiments, air shroud 105 may include air channels 201 and 202, down slope sections 203, 204, and 205 having one or more bypass ports 212, 213, and 214, memory covers 206, 207, and 208 having air mover openings 209, 210, and 211, and air movers 106 proximate to air shroud 105. In some embodiments, as shown in FIG. 3A, air movers 106 may comprise cooling fans. In other embodiments, as shown in FIG. 3B, air movers 106 may comprise blowers. Components 301 may be any suitable type of components including, but not limited to, peripheral component interconnect express (PCIe) cards. Information handling system 102 may include additional components without varying from the scope of this disclosure.

Air shroud 105 may be positioned in front of chassis-level air movers, such that air shroud 105 may direct airflow from the air movers into one of a plurality of channels and across multiple components downstream of the air movers, including, but not limited to, processor 103, heat sinks 302 and 303, memory 104, and other components 301. The first channel may include air channels 201 and 202 of air shroud 105. Air channel 201 may be located over a CPU and heat sink, for example processor 103 and heat sink 302, such that air channel 201 may direct airflow from the chassis-level air movers across the CPU and heat sink 302 and then out toward downstream components 301 of information handling system 102. Air channel 202 of air shroud 105 may be located over a CPU and heatsink, such as processor 103 and heat sink 303, such that air channel 202 may direct airflow from the chassis-level air movers across the CPU and heat sink 303 and then out toward downstream components 301 of information handling system 102.

In an example, bypass port 213 may be located between air channels 201 and 202, bypass port 212 may be located on an opposite side of air channel 201 as bypass port 213, and bypass port 214 may be located on an opposite side of air channel 202 as bypass port 213. Bypass port 212 may provide airflow that may travel along a memory cover 206 of air shroud 105, such that the airflow is not heated by memory 104 located on one side of the CPU below air channel 201. Similarly, bypass port 213 may provide airflow that may travel along a memory cover 207 of air shroud 105, such that the airflow is not heated by memory 104 located in between the CPUs below air channels 201 and 202. Additionally, bypass port 214 may provide airflow that may travel along a memory cover 208 of air shroud 105, such that the airflow is not heated by memory 104 located on another side of the CPU below air channel 202.

Air shroud 105 may direct airflow from the chassis-level air movers into a second channel of a plurality of channels. The second channel may be fluidically isolated from the first channel and may guide airflow from the chassis-level air movers over memory 104.

In the examples of FIGS. 3A and 3B, air shroud 105 having localized air movers 106 may, when air movers 106 are powered on, draw airflow generated from chassis-level air movers and expel the air from air movers 106 toward downstream components 301 of information handling system 102, including, but not limited to, PCIe cards, such that downstream components 301 may be cooled by airflow expelled from air movers 106. This airflow may also provide additional cooling to memories 104.

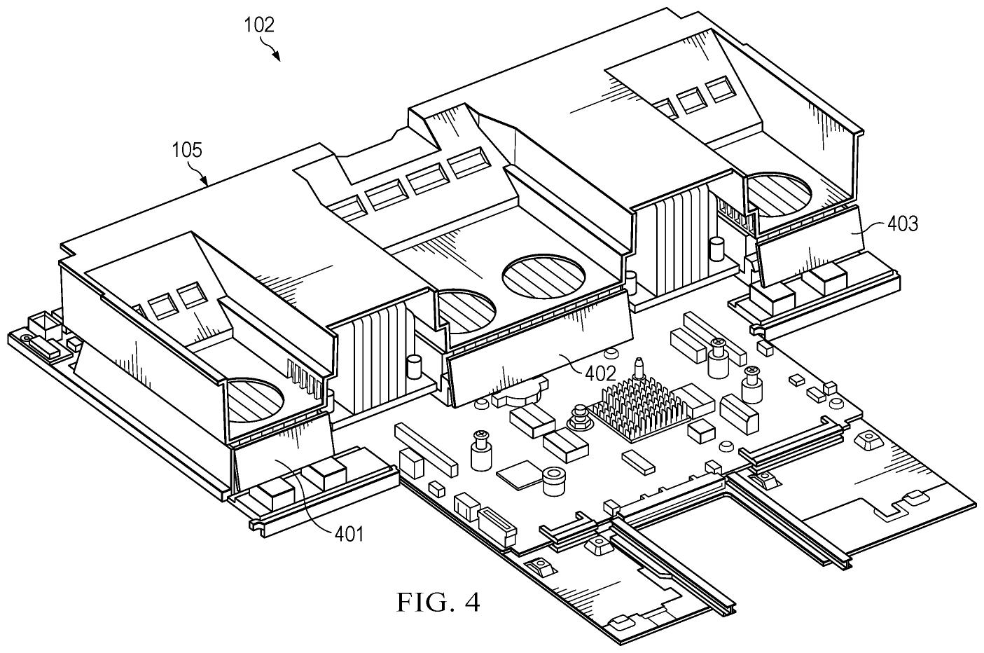

FIG. 4 illustrates an information handling system 102 including an air shroud 105 and air shroud flappers 401, 402, and 403 in accordance with embodiments of the present disclosure. Air shroud flappers 401, 402, and 403 may be configured to limit recirculation of airflow exhausted from air movers 106 when air movers 106 are powered on.

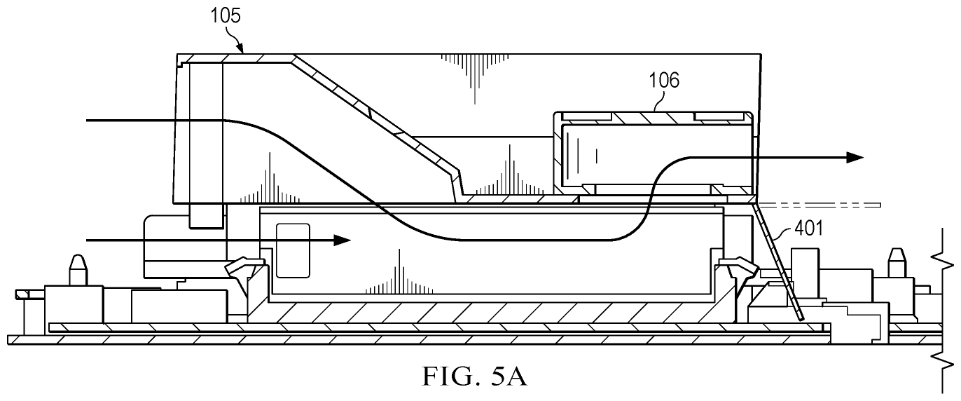

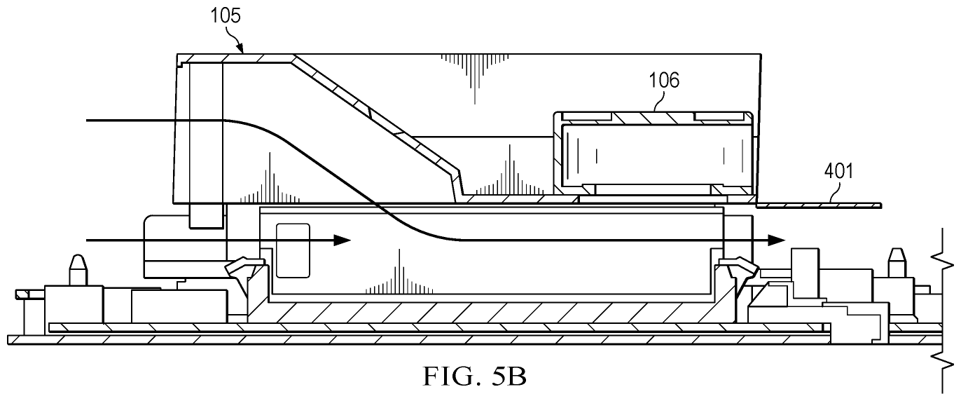

In an example, FIG. 5A illustrates how air flappers 401, 402, and 403 operate in accordance with embodiments of the present disclosure when air movers 106 are powered on. As shown in FIG. 5A, when air mover 106 is powered on, the suction of air mover 106 may draw air shroud flapper 401 to a closed position preventing air recirculation into information handling system components underneath air shroud 105.

However, as shown in FIG. 5B, when the same air mover 106 is powered off, air flapper 401 may remain in an extended open position. When air mover 106 is powered off and air flapper 401 is in an extended open position, air flow from chassis-level air movers is directed to components of information handling system 102 via air shroud 105 and flows through information handling system 102 toward downstream components of information handling system 102.

As shown in FIGS. 5A and 5B, air shroud 105 may include at least a first channel for guiding airflow over a first information handling resource (e.g., processor 103, heat sinks 302 and 303, CPU) and a second channel fluidically isolated from the first channel for guiding airflow over a second information handling resource (e.g., memory 104), and at least one opening (e.g., air mover openings 209, 210, 211) configured to fluidically couple between a respective internal air mover 106 and the second channel, such that the internal air mover 106 can operate in a plurality of modes determined by management controller 110, including: (a) a first mode in which the internal air mover 106 is powered off, such that airflow through the first channel and second channel is driven by chassis-level air movers; and (b) a second mode in which internal air mover 106 is powered on, such that airflow through the second channel is increased relative to the first mode. Operation in a plurality of modes allows dynamic control of airflow between the first channel and second channel (e.g., increase airflow to the second channel by operating in a mode where air mover 106 is powered on when memory 104 needs additional cooling).

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the FIGS. and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a chassis;
a plurality of information handling resources enclosed within the chassis and including a first information handling resource and a second information handling resource;
an air shroud enclosed within the chassis, and including a plurality of channels including at least:
a first channel configured to direct airflow driven by one or more chassis-level air movers from outside the chassis into the chassis and proximate to the first information handling resource; and
a second channel configured to direct airflow driven by the one or more chassis-level air movers from outside the chassis into the chassis and proximate to the second information handling resource; and
a shroud air mover mechanically coupled to the air shroud and fluidically coupled to the second channel via an opening formed in the air shroud and fluidically interfaced between the second channel and the shroud air mover, the shroud air mover configured to operate in a plurality of modes comprising:
a first mode in which the shroud air mover is inactive; and
a second mode in which the shroud air mover is active such that airflow through the second channel is greater in the second mode than in the first mode.

2. The information handling system of claim 1, further comprising a management controller configured to:
based on a temperature associated with the second information handling resource, determine a selected mode from the plurality of modes; and
control operation of the shroud air mover based on the selected mode.

3. The information handling system of claim 1, wherein:
the first information handling resource comprises a processor; and
the second information handling resource comprises a memory.

4. The information handling system of claim 1, further comprising a second opening formed in the air shroud and fluidically interfaced between the second channel and a volume of the chassis external to the air shroud.

5. The information handling system of claim 4, further comprising an air flapper mechanically coupled to the air shroud proximate to the second opening and configured to:
assume an open position in the first mode such that airflow through the second channel exits the air shroud via the second opening; and
assume a closed position in the second mode to prevent recirculation of air expelled from the shroud air mover.

6. The information handling system of claim 1, wherein the shroud air mover comprises a fan.

7. The information handling system of claim 1, wherein the shroud air mover comprises a blower.

8. An air shroud comprising:
a plurality of channels including at least:
a first channel configured to direct airflow driven by one or more chassis-level air movers from outside a chassis enclosing the air shroud into the chassis and into the first channel; and
a second channel configured to direct airflow driven by the one or more chassis-level air movers from outside the chassis into the chassis and into the second channel; and
an opening formed in the air shroud and fluidically configured to be interfaced between the second channel and a shroud air mover such that, when the shroud air mover operates in a plurality of modes comprising a first mode in which the shroud air mover is inactive and a second mode in which the shroud air mover is active, airflow through the second channel is greater in the second mode than in the first mode.

9. The air shroud of claim 8, further comprising a second opening formed in the air shroud and configured to fluidically interface between the second channel and a volume of the chassis external to the air shroud.

10. The air shroud of claim 9, further comprising an air flapper mechanically coupled to the air shroud proximate to the second opening and configured to:
assume an open position in the first mode such that airflow through the second channel exits the air shroud via the second opening; and
assume a closed position in the second mode to prevent recirculation of air expelled from the shroud air mover.

11. The air shroud of claim 8, wherein the shroud air mover comprises a fan.

12. The air shroud of claim 8, wherein the shroud air mover comprises a blower.

13. A method comprising, in a system having an air shroud enclosed within a chassis, and including a plurality of channels including at least a first channel configured to direct airflow driven by one or more chassis-level air movers from outside the chassis into the chassis and proximate to a first information handling resource and a second channel configured to direct airflow driven by one or more chassis-level air movers from outside the chassis into the chassis and proximate to a second information handling resource, and the system further comprising a shroud air mover mechanically coupled to the air shroud and fluidically coupled to the second channel via an opening formed in the air shroud and fluidically interfaced between the second channel and the shroud air mover, operating the shroud air mover in a plurality of modes including:
a first mode in which the shroud air mover is inactive; and
a second mode in which the shroud air mover is active such that airflow through the second channel is greater in the second mode than in the first mode.

14. The method of claim 13, further comprising:
based on a temperature associated with the second information handling resource, determining a selected mode from the plurality of modes; and
controlling operation of the shroud air mover based on the selected mode.

15. The method of claim 13, wherein:
the first information handling resource comprises a processor; and
the second information handling resource comprises a memory.

16. The method of claim 13, wherein the shroud air mover comprises a fan.

17. The method of claim 13, wherein the shroud air mover comprises a blower.
